(19) United States
(12) Patent Application Publication
(10) Pub. No.: US 2025/0266199 A1
(43) Pub. Date: Aug. 21, 2025

(54) ELECTRONIC COMPONENT

(71) Applicant: TDK Corporation, Tokyo (JP)

(72) Inventors: Tatsuki KAWASHIMA, Tokyo (JP); Jun NAKATSUTSUMI, Tokyo (JP)

(73) Assignee: TDK Corporation, Tokyo (JP)

(21) Appl. No.: 19/056,804

(22) Filed: Feb. 19, 2025

(30) Foreign Application Priority Data
Feb. 21, 2024 (JP) 2024-024936

(51) Int. Cl. H01F 17/00; H03H 5/00

(52) U.S. Cl. CPC H01F 17/0013; H01F 2017/002; H03H 5/00

(57) ABSTRACT

An electronic component includes an element body and an inductor. The inductor includes a first conductor, a second conductor, a third conductor, a fourth conductor, a fifth conductor, and a sixth conductor extending in a stacking direction of a plurality of element body layers, and a first inductor conductor, a second inductor conductor, a third inductor conductor, and a fourth inductor conductor. The first inductor conductor connects an end portion on one side of the first conductor in an extending direction and an end portion on one side of the second conductor in an extending direction. The second inductor conductor connects an end portion on the other side of the second conductor in the extending direction, an end portion on the other side of the third conductor in an extending direction, and an end portion on the other side of the fourth conductor in an extending direction.

### CROSS-REFERENCE TO RELATED APPLICATION

This application is based upon and claims the benefit of priority from Japanese Patent Application No. 2024-024936, filed on Feb. 21, 2024, the entire contents of which are incorporated herein by reference.

### TECHNICAL FIELD

The present disclosure relates to an electronic component.

### BACKGROUND

For example, an electronic component described in Japanese Unexamined Patent Publication No. 2011-244503 is known as an electronic component of the related art. The electronic component described in Japanese Unexamined Patent Publication No. 2011-244503 includes an element body formed by stacking a plurality of insulator layers, and an inductor disposed in the element body. The inductor includes two conductors extending in a stacking direction of the plurality of insulator layers, and a connection conductor connecting two conductors.

### SUMMARY

An object of one aspect of the present disclosure is to provide an electronic component capable of improving a Q-value.

(1) An electronic component according to one aspect of the present disclosure includes an element body formed by stacking a plurality of insulator layers, and an inductor disposed in the element body. The inductor includes a first conductor, a second conductor, a third conductor, a fourth conductor, a fifth conductor, and a sixth conductor extending in a stacking direction of the plurality of insulator layers, and a first connection conductor, a second connection conductor, a third connection conductor, and a fourth connection conductor, the first connection conductor connects an end portion on one side of the first conductor in an extending direction of the first conductor and an end portion on one side of the second conductor in an extending direction of the second conductor, the second connection conductor connects an end portion on the other side of the second conductor in the extending direction, an end portion on the other side of the third conductor in an extending direction of the third conductor, and an end portion on the other side of the fourth conductor in an extending direction of the fourth conductor, the third connection conductor connects an end portion on one side of the third conductor in the extending direction and an end portion on one side of the fifth conductor in an extending direction of the fifth conductor, and the fourth connection conductor connects an end portion on one side in the extending direction of the fourth conductor and an end portion on one side of the sixth conductor in an extending direction of the sixth conductor.

In the electronic component according to one aspect of the present disclosure, the second connection conductor connects the end portion on the other side of the second conductor, the end portion on the other side of the third conductor, and the end portion on the other side of the fourth conductor. As described above, in the electronic component, one conductor (second conductor) and two conductors (third conductor and fourth conductor) are connected by the second connection conductor. As a result, in the electronic component, the inductance can be secured in the inductor. Therefore, in the electronic component, the Q-value can be improved.

(2) In the electronic component of the above (1), the second connection conductor may include two members.

(3) In the electronic component of the above (1) or (2), the first conductor may be disposed between the third conductor and the fourth conductor in a direction orthogonal to a facing direction in which the first conductor and the second conductor face each other as viewed from the stacking direction. In this configuration, the first conductor, the third conductor, and the fourth conductor are disposed side by side in the element body. As a result, in the electronic component, space saving of the disposition of the first conductor, the third conductor, and the fourth conductor in the element body can be achieved while realizing the configuration in which the second conductor, the third conductor, and the fourth conductor are connected by the second connection conductor. Thus, the electronic component can be downsized.

(4) In the electronic component according to any one of the above (1) to (3), the second conductor may be disposed between the fifth conductor and the sixth conductor in a direction orthogonal to a facing direction in which the first conductor and the second conductor face each other as viewed from the stacking direction. In this configuration, the second conductor, the fifth conductor, and the sixth conductor are disposed side by side in the element body. As a result, in the electronic component, space saving of disposition of the second conductor, the fifth conductor, and the sixth conductor in the element body can be achieved. Thus, the electronic component can be downsized.

(5) In the electronic component according to any one of the above (1) to (4), the second connection conductor may have a structure that is line-symmetric with respect to a straight line connecting the first conductor and the second conductor as viewed from the stacking direction. In this configuration, variations in characteristics of the inductor can be suppressed.

(6) In the electronic component according to any one of the above (1) to (5), the first conductor may include a plurality of via conductors.

(7) In the electronic component according to any one of the above (1) to (6), the second conductor may include a plurality of via conductors.

(8) In the electronic component according to any one of the above (1) to (7), a sectional area of a section orthogonal to the extending direction of at least one of the first conductor and the second conductor may be greater than a sectional area of a section orthogonal to the extending direction of each of the third conductor, the fourth conductor, the fifth conductor, and the sixth conductor.

(9) In the electronic component according to any one of the above (1) to (8), a width of the first connection conductor may be greater than a width of each of the third connection conductor and the fourth connection conductor as viewed from the stacking direction.

According to one aspect of the present disclosure, the Q-value can be improved.

### BRIEF DESCRIPTION OF THE DRAWINGS

FIG. 1 is a transparent perspective view of an electronic component according to a first embodiment;

FIG. 2 is a transparent perspective view of the electronic component illustrated in FIG. 1;

FIG. 3 is a side view of the electronic component illustrated in FIG. 1;

FIG. 4 is an end view of the electronic component illustrated in FIG. 1;

FIG. 5 is an exploded perspective view of the electronic component illustrated in FIG. 1;

FIG. 6 is a diagram illustrating a second inductor conductor;

FIG. 7 is an equivalent circuit diagram of the electronic component illustrated in FIG. 1;

FIG. 8 is a transparent perspective view of an electronic component according to a second embodiment;

FIG. 9 is a transparent perspective view of the electronic component illustrated in FIG. 8;

FIG. 10 is a side view of the electronic component illustrated in FIG. 8; and

FIG. 11 is a diagram illustrating a sectional configuration of a conductor according to another embodiment.

### DETAILED DESCRIPTION

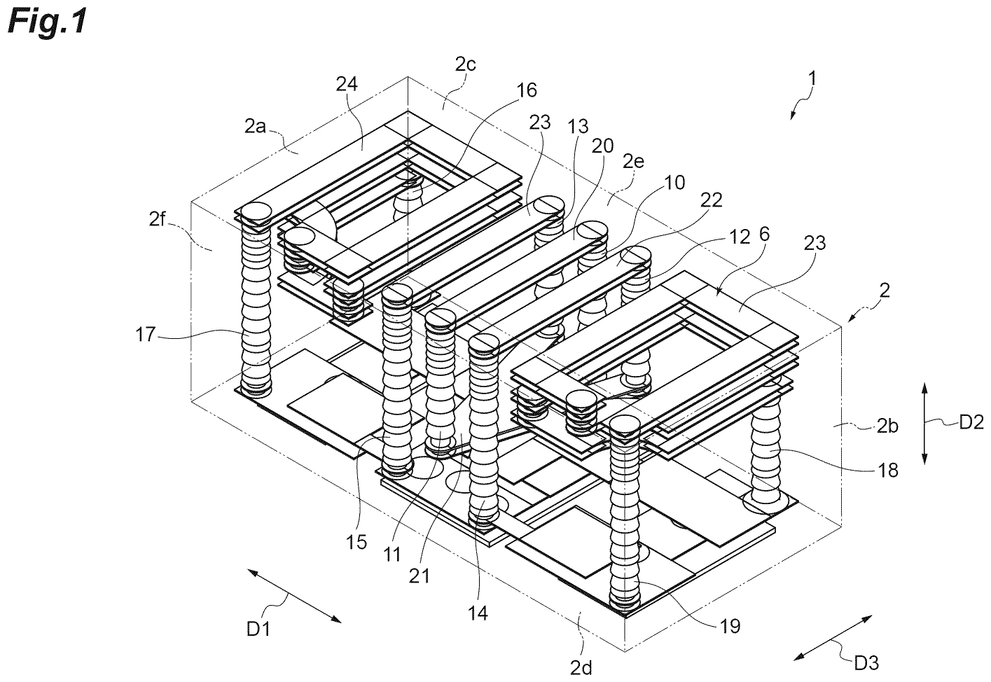

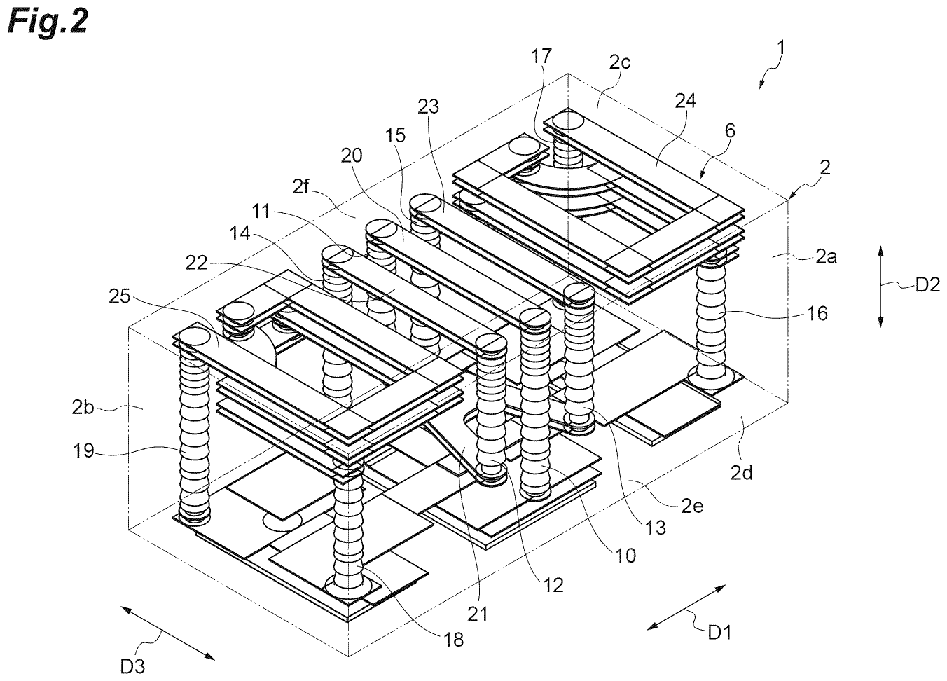

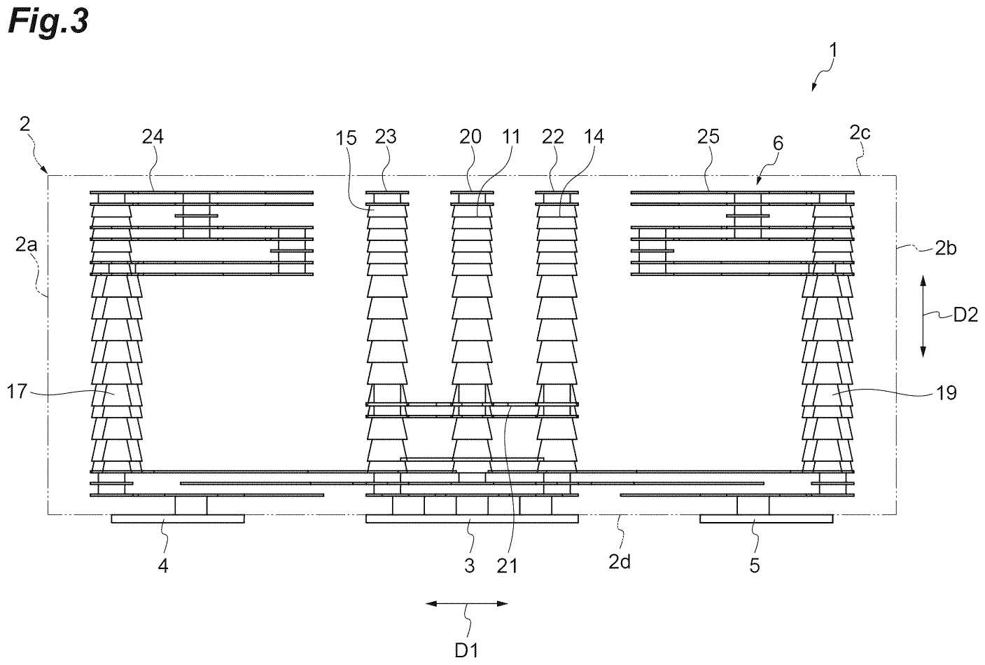

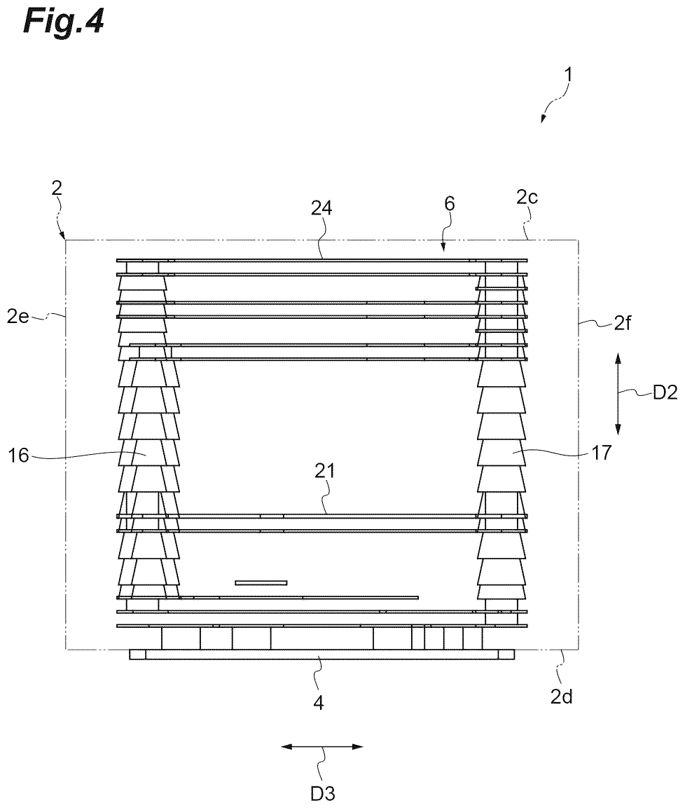

Hereinafter, preferred embodiments of the present disclosure will be described in detail with reference to the accompanying drawings. Note that, the same or corresponding elements in the description of the drawings are denoted by the same reference signs, and redundant description is omitted.

[First Embodiment] An electronic component according to a first embodiment will be described with reference to FIGS. 1, 2, 3, and 4. FIG. 1 is a transparent perspective view of the electronic component according to the first embodiment. FIG. 2 is a transparent perspective view of the electronic component illustrated in FIG. 1. FIG. 3 is a side view of the electronic component illustrated in FIG. 1. FIG. 4 is an end view of the electronic component illustrated in FIG. 1. As illustrated in FIGS. 1 to 4, an electronic component 1 includes an element body 2, a first terminal electrode 3, a second terminal electrode 4, a third terminal electrode 5, and a resonator 6. In FIGS. 1 to 4, the element body 2 is indicated by a dashed double-dotted line.

The element body 2 has a rectangular parallelepiped shape. The rectangular parallelepiped shape includes a rectangular parallelepiped shape in which corner parts and ridge line parts are chamfered, or a rectangular parallelepiped shape in which corner parts and ridge line parts are rounded. The element body 2 has, as outer surfaces, a pair of end surfaces 2a and 2b, a pair of main surfaces 2c and 2d, and a pair of side surfaces 2e and 2f. The end surfaces 2a and 2b face each other. The main surfaces 2c and 2d face each other. The side surfaces 2e and 2f face each other. In the following description, a facing direction of the end surfaces 2a and 2b is referred to as a first direction D1, a facing direction of the main surfaces 2c and 2d is referred to as a second direction D2, and a facing direction of the side surfaces 2e and 2f is referred to as a third direction D3. The first direction D1, the second direction D2, and the third direction D3 are substantially orthogonal to each other.

The end surfaces 2a and 2b extend in the second direction D2 so as to be connected to the main surfaces 2c and 2d. The end surfaces 2a and 2b also extend in the third direction D3 so as to link the side surfaces 2e and 2f. The main surfaces 2c and 2d extend in the first direction D1 so as to link the end surfaces 2a and 2b. The main surfaces 2c and 2d also extend in the third direction D3 so as to link the side surfaces 2e and 2f. The side surfaces 2e and 2f extend in the first direction D1 so as to link the end surfaces 2a and 2b. The side surfaces 2e and 2f also extend in the second direction D2 so as to be connected to the main surfaces 2c and 2d.

The main surface 2d is an implementation surface, for example, a surface facing another electronic device (for example, circuit base material or multilayer electronic component) when the electronic component 1 is implemented on the another electronic device (not illustrated). The end surfaces 2a and 2b are surfaces continuous from the implementation surface (that is, the main surface 2d).

A length of the element body 2 in the first direction D1 is longer than a length of the element body 2 in the second direction D2 and a length of the element body 2 in the third direction D3. The length of the element body 2 in the second direction D2 is shorter than the length of the element body 2 in the third direction D3. In other words, in the present embodiment, the end surfaces 2a and 2b, the main surfaces 2c and 2d, and the side surfaces 2e and 2f each have an oblong shape. The length of the element body 2 in the second direction D2 may be equal to the length of the element body 2 in the third direction D3, or may be longer than the length of the element body 2 in the third direction D3.

It should be noted that “equal” in the present embodiment may mean not only “equal” but also a value including a slight difference, a manufacturing error, or the like in a preset range. For example, when a plurality of values are included within a range of +5% of an average value of the plurality of values, the plurality of values are defined to be equal.

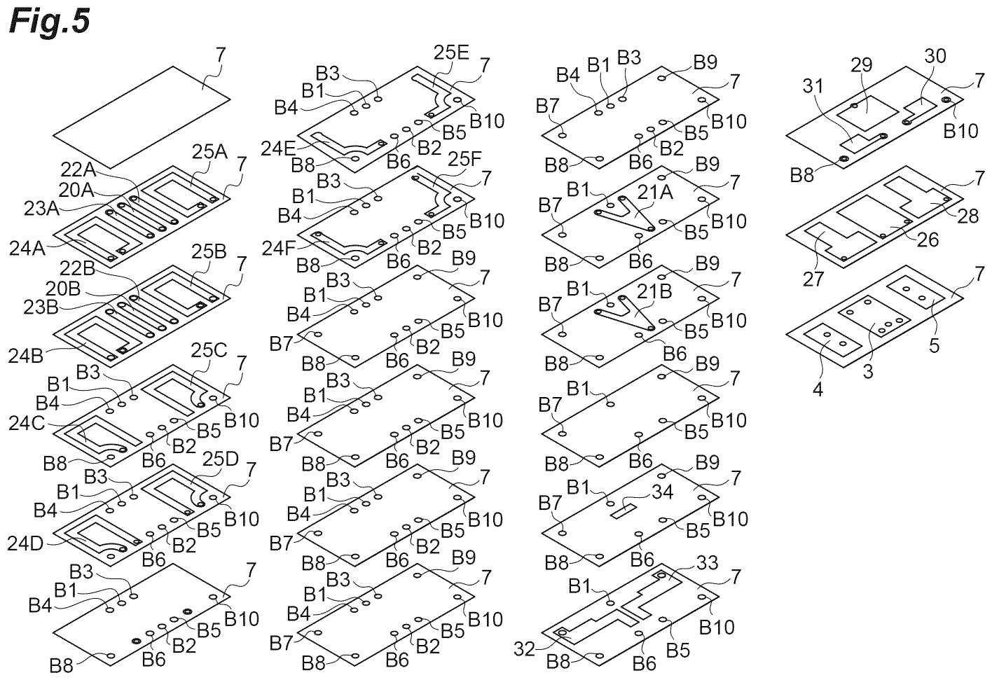

The element body 2 is formed by stacking a plurality of element body layers (insulator layers) 7 (see FIG. 5) in the second direction D2. In other words, a stacking direction of the element body 2 is the second direction D2. In the actual element body 2, the plurality of element body layers 7 may be integrated to such an extent that boundaries between the layers cannot be visually recognized, or may be integrated such that boundaries between the layers can be visually recognized.

The element body layer 7 is formed by using, for example, a sintered body of a ceramic green sheet containing a dielectric material. The dielectric material includes, for example, at least one selected from a BaTiO₃ based material, a Ba(Ti, Zr)O₃ based material, a (Ba, Ca)TiO₃ based material, a glass material, or an alumina material.

Each of the first terminal electrode 3, the second terminal electrode 4, and the third terminal electrode 5 is provided in the element body 2. Each of the first terminal electrode 3, the second terminal electrode 4, and the third terminal electrode 5 is disposed on the main surface 2d of the element body 2. Each of the first terminal electrode 3, the second terminal electrode 4, and the third terminal electrode 5 may have an oblong shape (rectangular shape). Each of the first terminal electrode 3, the second terminal electrode 4, and the third terminal electrode 5 is disposed such that each side is along the first direction D1 or the third direction D3. In the present embodiment, a length of the first terminal electrode 3 in the first direction D1 is longer than lengths of the second terminal electrode 4 and the third terminal electrode 5 in the first direction D1.

As illustrated in FIG. 3, the first terminal electrode 3, the second terminal electrode 4, and the third terminal electrode 5 are disposed apart from each other in the first direction D1. The first terminal electrode 3 is disposed at a central position in the first direction D1 on the main surface 2d. The second terminal electrode 4 is disposed at a position closer to the end surface 2a on the main surface 2d. The third terminal electrode 5 is disposed at a position closer to the end surface 2b on the main surface 2d. The first terminal electrode 3 is disposed between the second terminal electrode 4 and the third terminal electrode 5 in the first direction D1.

Each of the first terminal electrode 3, the second terminal electrode 4, and the third terminal electrode 5 protrudes from the main surface 2d. That is, in the present embodiment, surfaces of the first terminal electrode 3, the second terminal electrode 4, and the third terminal electrode 5 are not flush with the main surface 2d. The first terminal electrode 3, the second terminal electrode 4, and the third terminal electrode 5 are made of a conductive material (for example, Cu).

A plating layer (not illustrated) containing, for example, Ni, Sn, Au, or the like may be provided in each of the first terminal electrode 3, the second terminal electrode 4, and the third terminal electrode 5 by electrolytic plating or non-electrolytic plating. The plating layer may have a Ni plating film covering the first terminal electrode 3, the second terminal electrode 4, and the third terminal electrode 5, and an Au plating film containing Au and covering the Ni plating film.

FIG. 5 is an exploded perspective view of the electronic component 1 illustrated in FIG. 1. As illustrated in FIGS. 1 to 5, the resonator 6 includes a first conductor 10, a second conductor 11, a third conductor 12, a fourth conductor 13, a fifth conductor 14, a sixth conductor 15, a seventh conductor 16, an eighth conductor 17, a ninth conductor 18, a tenth conductor 19, a first inductor conductor (first connection conductor) 20, a second inductor conductor (second connection conductor) 21, a third inductor conductor (third connection conductor) 22, a fourth inductor conductor (fourth connection conductor) 23, a fifth inductor conductor 24, a sixth inductor conductor 25, a capacitor conductor 26, a capacitor conductor 27, a capacitor conductor 28, a capacitor conductor 29, a capacitor conductor 30, a capacitor conductor 31, a capacitor conductor 32, a capacitor conductor 33, and a capacitor conductor 34.

The first conductor 10 extends along the second direction D2. The first conductor 10 can include a plurality of via conductors B1. The first conductor 10 is disposed at a position closer to the side surface 2e at a central position in the first direction D1.

The second conductor 11 extends along the second direction D2. The second conductor 11 can include a plurality of via conductors B2. The second conductor 11 is disposed at a position closer to the side surface 2f at a central position in the first direction D1. The second conductor 11 is disposed at a position facing the first conductor 10 in the third direction D3.

The third conductor 12 extends along the second direction D2. The third conductor 12 can include a plurality of via conductors B3. The third conductor 12 is disposed at a position closer to the side surface 2e at a position closer to a center in the first direction D1. The third conductor 12 is disposed at a position closer to the end surface 2b than the first conductor 10. In the present embodiment, the third conductor 12 is disposed on the same straight line as the first conductor 10 in the first direction D1.

The fourth conductor 13 extends along the second direction D2. The fourth conductor 13 can include a plurality of via conductors B4. The fourth conductor 13 is disposed at a position closer to the side surface 2e at a position closer to a center in the first direction D1. The fourth conductor 13 is disposed at a position closer to the end surface 2a than the first conductor 10. In the present embodiment, the fourth conductor 13 is disposed on the same straight line as the first conductor 10 in the first direction D1. The third conductor 12 and the fourth conductor 13 are disposed at positions sandwiching the first conductor 10 in the first direction D1. That is, the first conductor 10 is disposed between the third conductor 12 and the fourth conductor 13 in the first direction D1 (direction orthogonal to the facing direction in which the first conductor 10 and the second conductor 11 face each other) as viewed from the second direction D2.

The fifth conductor 14 extends along the second direction D2. The fifth conductor 14 can include a plurality of via conductors B5. The fifth conductor 14 is disposed at a position closer to the side surface 2f at a position closer to a center in the first direction D1. The fifth conductor 14 is disposed at a position closer to the end surface 2b than the second conductor 11. In the present embodiment, the fifth conductor 14 is disposed on the same straight line as the second conductor 11 in the first direction D1.

The sixth conductor 15 extends along the second direction D2. The sixth conductor 15 can include a plurality of via conductors B6. The sixth conductor 15 is disposed at a position closer to the side surface 2f at a position closer to a center in the first direction D1. The sixth conductor 15 is disposed at a position closer to the end surface 2a than the second conductor 11. In the present embodiment, the sixth conductor 15 is disposed on the same straight line as the second conductor 11 in the first direction D1. The fifth conductor 14 and the sixth conductor 15 are disposed at positions sandwiching the second conductor 11 in the first direction D1. That is, the second conductor 11 is disposed between the fifth conductor 14 and the sixth conductor 15 in the first direction D1 as viewed from the second direction D2.

The seventh conductor 16 extends along the second direction D2. The seventh conductor 16 can include a plurality of via conductors B7. The seventh conductor 16 is disposed at a position closer to the side surface 2e at a position closer to the end surface 2a.

The eighth conductor 17 extends along the second direction D2. The eighth conductor 17 can include a plurality of via conductors B8. The eighth conductor 17 is disposed at a position closer to the side surface 2f at a position closer to the end surface 2a. The eighth conductor 17 is disposed at a position facing the seventh conductor 16 in the third direction D3.

The ninth conductor 18 extends along the second direction D2. The ninth conductor 18 can include a plurality of via conductors B9. The ninth conductor 18 is disposed at a position closer to the side surface 2e at a position closer to the end surface 2b. In the present embodiment, the ninth conductor 18 is disposed on the same straight line as the first conductor 10, the third conductor 12, the fourth conductor 13, and the seventh conductor 16 in the first direction D1.

The tenth conductor 19 extends along the second direction D2. The tenth conductor 19 can include a plurality of via conductors B10. The tenth conductor 19 is disposed at a position closer to the side surface 2f at a position closer to the end surface 2b. The tenth conductor 19 is disposed at a position facing the ninth conductor 18 in the third direction D3. In the present embodiment, the tenth conductor 19 is disposed on the same straight line as the second conductor 11, the fifth conductor 14, the sixth conductor 15, and the eighth conductor 17 in the first direction D1.

The first inductor conductor 20 electrically connects the first conductor 10 and the second conductor 11. The first inductor conductor 20 connects an end portion on one side (main surface 2c side) of the first conductor 10 and an end portion on one side of the second conductor 11. The first inductor conductor 20 extends along the third direction D3. In the present embodiment, the end portion means a portion on the main surface 2c side or the main surface 2d side with respect to a central position in an extending direction of the first conductor 10 (second direction D2) in the extending direction. The end portion on one side means a portion on the main surface 2c side, and the end portion on the other side means a portion on the main surface 2d side.

The first inductor conductor 20 includes an inductor pattern 20A and an inductor pattern 20B. The inductor pattern 20A and the inductor pattern 20B have the same shape. The inductor pattern 20A and the inductor pattern 20B are disposed to face each other in the second direction D2.

The second inductor conductor 21 electrically connects the second conductor 11 to the third conductor 12 and the fourth conductor 13. The second inductor conductor 21 connects an end portion on the other side (the main surface 2d side) of the second conductor 11 and an end portion on the other side of the third conductor 12. The second inductor conductor 21 connects the end portion on the other side of the second conductor 11 and an end portion on the other side of the fourth conductor 13. The second inductor conductor 21 includes an inductor pattern 21A and an inductor pattern 21B. The inductor pattern 21A and the inductor pattern 21B have the same shape. The inductor pattern 21A and the inductor pattern 21B are disposed to face each other in the second direction D2.

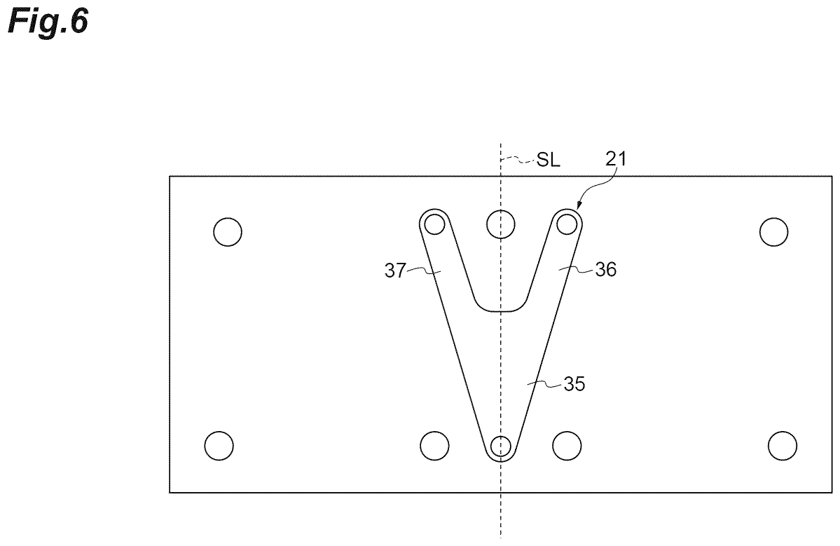

FIG. 6 is a diagram illustrating the second inductor conductor 21. As illustrated in FIG. 6, the second inductor conductor 21 (inductor patterns 21A and 21B) has a substantially V-shape. The second inductor conductor 21 has a line-symmetric shape as viewed from the second direction D2. The second inductor conductor 21 has a structure that is line-symmetric with respect to a straight line SL connecting the first conductor 10 and the second conductor 11 in the facing direction (third direction D3) of the first conductor 10 and the second conductor 11. The second inductor conductor 21 includes a first portion 35, a second portion 36, and a third portion 37. The first portion 35, the second portion 36, and the third portion 37 are integrally formed. The first portion 35 is a portion to which the second conductor 11 is connected. The second portion 36 extends (protrudes) from the first portion 35 and is a portion to which the third conductor 12 is connected. The third portion 37 extends from the first portion 35 and is a portion to which the fourth conductor 13 is connected.

As illustrated in FIGS. 1 to 5, the third inductor conductor 22 electrically connects the third conductor 12 and the fifth conductor 14. The third inductor conductor 22 connects an end portion on one side of the third conductor 12 and an end portion on one side of the fifth conductor 14. The third inductor conductor 22 extends along the third direction D3. The third inductor conductor 22 includes an inductor pattern 22A and an inductor pattern 22B. The inductor pattern 22A and the inductor pattern 22B have the same shape. The inductor pattern 22A and the inductor pattern 22B are disposed to face each other in the second direction D2.

The fourth inductor conductor 23 electrically connects the fourth conductor 13 and the sixth conductor 15. The fourth inductor conductor 23 connects an end portion on one side of the fourth conductor 13 and an end portion on one side of the sixth conductor 15. The fourth inductor conductor 23 extends along the third direction D3. The fourth inductor conductor 23 includes an inductor pattern 23A and an inductor pattern 23B. The inductor pattern 23A and the inductor pattern 23B have the same shape. The inductor pattern 23A and the inductor pattern 23B are disposed to face each other in the second direction D2.

The fifth inductor conductor 24 electrically connects the seventh conductor 16 and the eighth conductor 17. The fifth inductor conductor 24 connects an end portion on one side of the seventh conductor 16 and an end portion on one side of the eighth conductor 17. The fifth inductor conductor 24 includes an inductor pattern 24A, an inductor pattern 24B, an inductor pattern 24C, an inductor pattern 24D, an inductor pattern 24E, and an inductor pattern 24F.

The inductor pattern 24A and the inductor pattern 24B have the same shape. The inductor pattern 24A and the inductor pattern 24B are disposed to face each other in the second direction D2. The inductor pattern 24C and the inductor pattern 24D have the same shape. The inductor pattern 24C and the inductor pattern 24D are disposed to face each other in the second direction D2. The inductor pattern 24E and the inductor pattern 24F have the same shape. The inductor pattern 24E and the inductor pattern 24F are disposed to face each other in the second direction D2.

The sixth inductor conductor 25 electrically connects the ninth conductor 18 and the tenth conductor 19. The sixth inductor conductor 25 connects an end portion on one side of the ninth conductor 18 and an end portion on one side of the tenth conductor 19. The sixth inductor conductor 25 includes an inductor pattern 25A, an inductor pattern 25B, an inductor pattern 25C, an inductor pattern 25D, an inductor pattern 25E, and an inductor pattern 25F.

The inductor pattern 25A and the inductor pattern 25B have the same shape. The inductor pattern 25A and the inductor pattern 25B are disposed to face each other in the second direction D2. The inductor pattern 25C and the inductor pattern 25D have the same shape. The inductor pattern 25C and the inductor pattern 25D are disposed to face each other in the second direction D2. The inductor pattern 25E and the inductor pattern 25F have the same shape. The inductor pattern 25E and the inductor pattern 25F are disposed to face each other in the second direction D2.

The capacitor conductor 26 is electrically connected to the first terminal electrode 3. The capacitor conductor 27 is electrically connected to the second terminal electrode 4. The capacitor conductor 28 is electrically connected to the third terminal electrode 5.

The capacitor conductor 29 is connected to an end portion on the other side of the first conductor 10. The capacitor conductor 29 is disposed at a position facing the capacitor conductor 26 in the second direction D2. The capacitor conductor 30 is connected to an end portion on the other side of the fifth conductor 14. The capacitor conductor 30 is disposed at a position facing the capacitor conductor 28 in the second direction D2. The capacitor conductor 31 is connected to an end portion on the other side of the sixth conductor 15. The capacitor conductor 31 is disposed at a position facing the capacitor conductor 27 in the second direction D2.

The capacitor conductor 32 is connected to an end portion on the other side of the seventh conductor 16. A part of the capacitor conductor 32 is disposed at a position facing the capacitor conductor 29 in the second direction D2. The capacitor conductor 33 is connected to an end portion on the other side of the ninth conductor 18. A part of the capacitor conductor 33 is disposed at a position facing the capacitor conductor 29 in the second direction D2. The capacitor conductor 34 is disposed at a position facing each of the capacitor conductor 32 and the capacitor conductor 33 in the second direction D2.

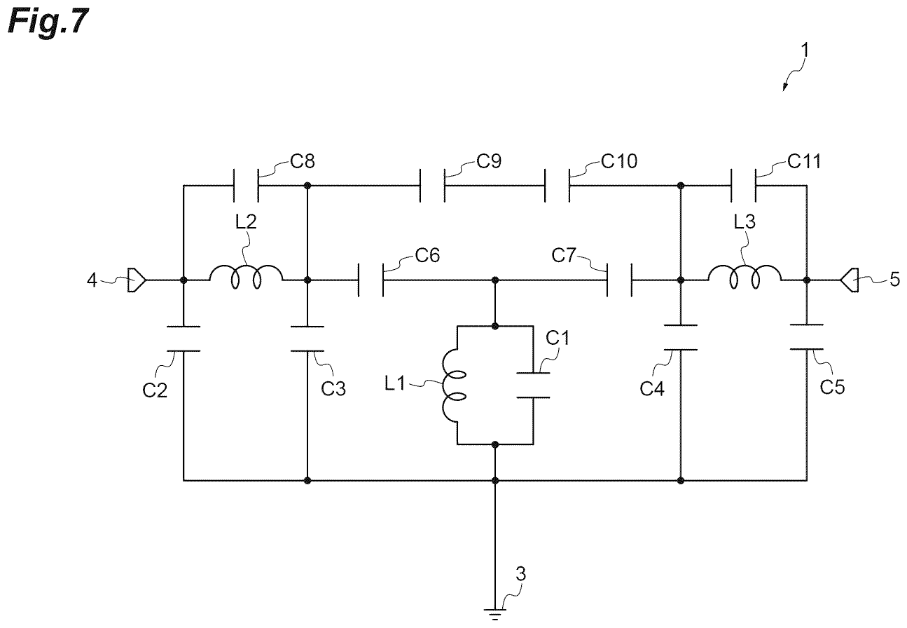

FIG. 7 is an equivalent circuit diagram of the electronic component 1 illustrated in FIG. 1. As illustrated in FIG. 7, the electronic component 1 includes a first inductor (inductor) L1, a second inductor L2, a third inductor L3, a first capacitor C1, a second capacitor C2, a third capacitor C3, a fourth capacitor C4, a fifth capacitor C5, a sixth capacitor C6, a seventh capacitor C7, an eighth capacitor C8, a ninth capacitor C9, a tenth capacitor C10, and an eleventh capacitor C11.

The first inductor L1 includes the first conductor 10, the second conductor 11, the third conductor 12, the fourth conductor 13, the fifth conductor 14, the sixth conductor 15, the first inductor conductor 20, the second inductor conductor 21, the third inductor conductor 22, and the fourth inductor conductor 23. The second inductor L2 includes the seventh conductor 16, the eighth conductor 17, and the fifth inductor conductor 24. The third inductor L3 includes the ninth conductor 18, the tenth conductor 19, and the sixth inductor conductor 25.

The first capacitor C1 includes the capacitor conductor 26 and the capacitor conductor 29. The second capacitor C2 includes the capacitor conductor 27 and the capacitor conductor 31. The third capacitor C3 includes the capacitor conductor 26 and the capacitor conductor 32. The fourth capacitor C4 includes the capacitor conductor 26 and the capacitor conductor 33. The fifth capacitor C5 includes the capacitor conductor 28 and the capacitor conductor 30.

The sixth capacitor C6 includes the capacitor conductor 29 and the capacitor conductor 32. The seventh capacitor C7 includes the capacitor conductor 29 and the capacitor conductor 33. The eighth capacitor C8 includes the capacitor conductor 27 and the capacitor conductor 32. The ninth capacitor C9 includes the capacitor conductor 32 and the capacitor conductor 34. The tenth capacitor C10 includes the capacitor conductor 33 and the capacitor conductor 34. The eleventh capacitor C11 includes the capacitor conductor 28 and the capacitor conductor 33.

As described above, in the electronic component 1 according to the present embodiment, the second inductor conductor 21 connects the end portion on the other side of the second conductor 11, the end portion on the other side of the third conductor 12, and the end portion on the other side of the fourth conductor 13. As described above, in the electronic component 1, one conductor (second conductor 11) and two conductors (third conductor 12 and fourth conductor 13) are connected by the second inductor conductor 21. As a result, in the electronic component 1, an inductance can be secured in an inductor of the resonator 6. Therefore, in the electronic component 1, a Q-value can be improved.

In the electronic component 1 according to the present embodiment, the first conductor 10 is disposed between the third conductor 12 and the fourth conductor 13 in the direction (first direction D1) orthogonal to the facing direction (third direction D3) in which the first conductor 10 and the second conductor 11 face each other as viewed from the second direction D2. In this configuration, the first conductor 10, the third conductor 12, and the fourth conductor 13 are disposed side by side in the element body 2. As a result, in the electronic component 1, space saving of the disposition of the first conductor 10, the third conductor 12, and the fourth conductor 13 in the element body 2 can be achieved while realizing the configuration in which the second conductor 11, the third conductor 12, and the fourth conductor 13 are connected by the second inductor conductor 21. Thus, the electronic component 1 can be downsized.

In the electronic component 1 according to the present embodiment, the second conductor 11 is disposed between the fifth conductor 14 and the sixth conductor 15 in the direction (first direction D1) orthogonal to the facing direction (third direction D3) in which the first conductor 10 and the second conductor 11 face each other as viewed from the second direction D2. In this configuration, the second conductor 11, the fifth conductor 14, and the sixth conductor 15 are disposed side by side in the element body 2. As a result, in the electronic component 1, space saving of the disposition of the second conductor 11, the fifth conductor 14, and the sixth conductor 15 in the element body 2 can be achieved. Thus, the electronic component 1 can be downsized.

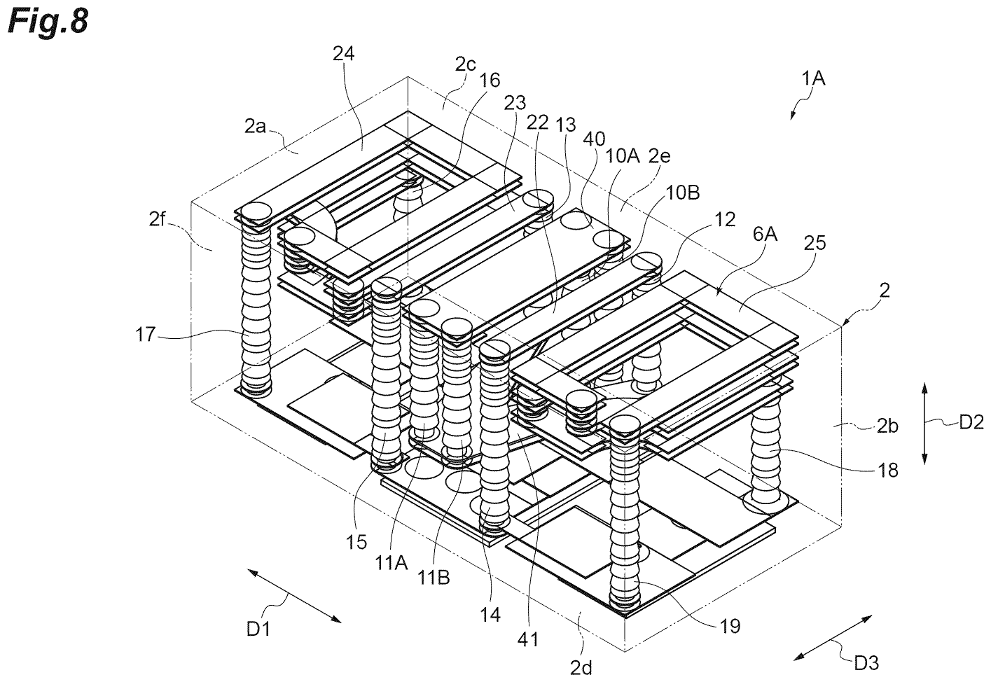

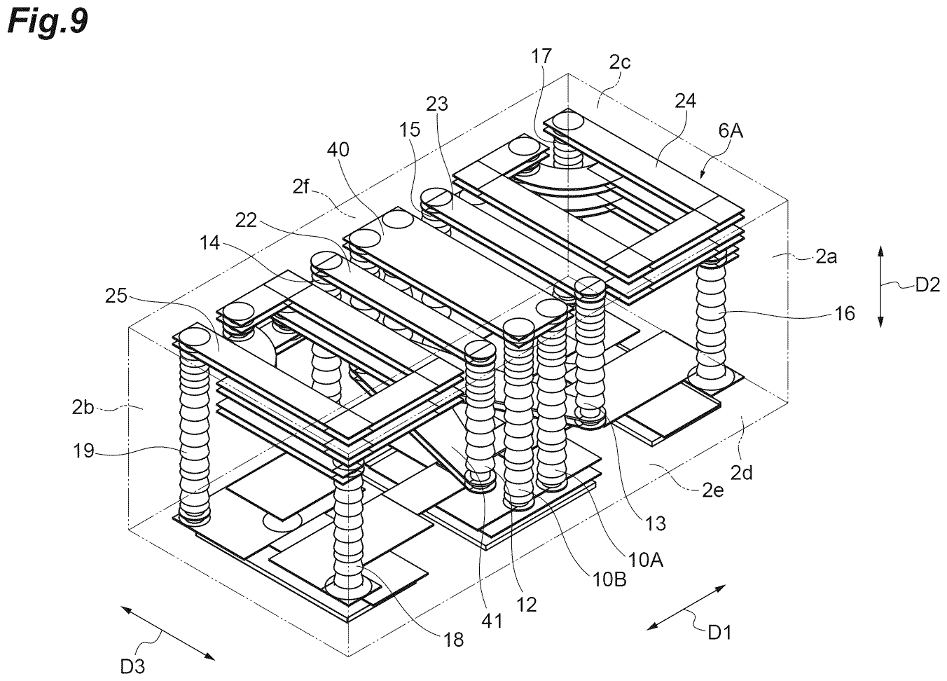

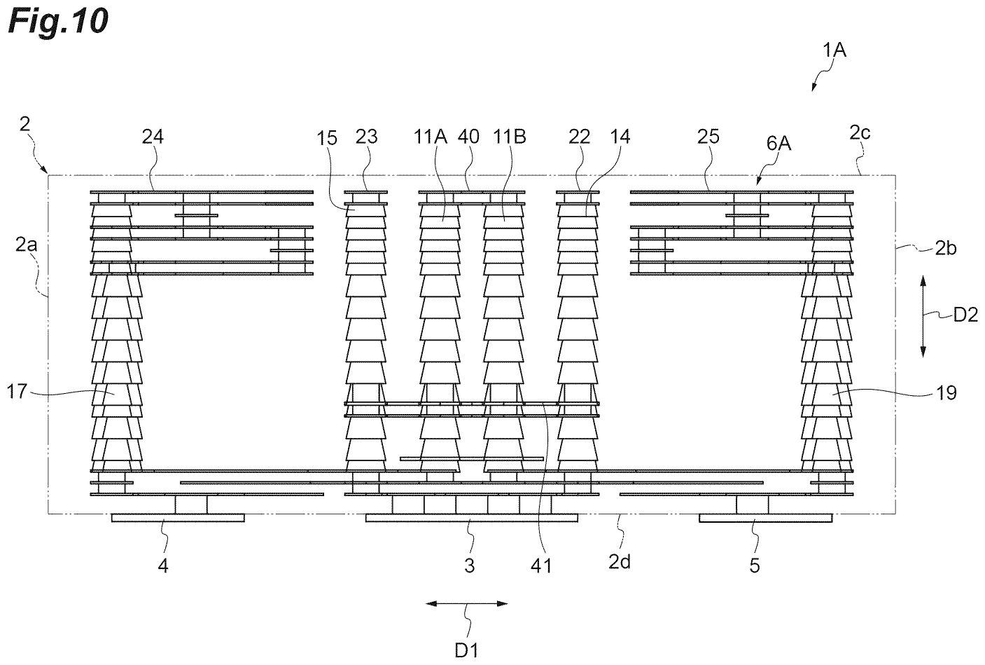

In the electronic component 1 according to the present embodiment, the second inductor conductor 21 has a structure that is line-symmetric with respect to the straight line SL connecting the first conductor 10 and the second conductor 11 as viewed from the second direction D2. In this configuration, variations in characteristics of the inductor can be suppressed.

[Second Embodiment] Next, a second embodiment will be described. FIG. 8 is a transparent perspective view of an electronic component according to a second embodiment. FIG. 9 is a transparent perspective view of the electronic component illustrated in FIG. 8. FIG. 10 is a side view of the electronic component illustrated in FIG. 8. As illustrated in FIGS. 8 to 10, an electronic component 1A includes an element body 2, a first terminal electrode 3, a second terminal electrode 4, a third terminal electrode 5, and a resonator 6A. In FIGS. 8 and 9, the element body 2 is indicated by a dashed double-dotted line.

The resonator 6A includes first conductors 10A and 10B, second conductors 11A and 11B, a third conductor 12, a fourth conductor 13, a fifth conductor 14, a sixth conductor 15, a seventh conductor 16, an eighth conductor 17, a ninth conductor 18, a tenth conductor 19, a first inductor conductor (first connection conductor) 40, a second inductor conductor (second connection conductor) 41, a third inductor conductor (third connection conductor) 22, a fourth inductor conductor (fourth connection conductor) 23, a fifth inductor conductor 24, a sixth inductor conductor 25, a capacitor conductor 26, a capacitor conductor 27, a capacitor conductor 28, a capacitor conductor 29, a capacitor conductor 30, a capacitor conductor 31, a capacitor conductor 32, a capacitor conductor 33, and a capacitor conductor 34.

The first conductor 10A extends along a second direction D2. The first conductor 10A can include a plurality of via conductors B1. The first conductor 10A is disposed at a position closer to a side surface 2e at a position closer to a center in a first direction D1. The first conductor 10B extends along the second direction D2. The first conductor 10B can include a plurality of via conductors B1. The first conductor 10B is disposed at a position closer to the side surface 2e at a position closer to a center in the first direction D1.

The second conductor 11A extends along the second direction D2. The second conductor 11A can include a plurality of via conductors B2. The second conductor 11A is disposed at a position closer to a side surface 2f at a central position in the first direction D1. The second conductor 11A is disposed at a position facing the first conductor 10A in a third direction D3. The second conductor 11B extends along the second direction D2. The second conductor 11B can include a plurality of via conductors B2. The second conductor 11B is disposed at a position closer to the side surface 2f at a central position in the first direction D1. The second conductor 11B is disposed at a position facing the first conductor 10B in the third direction D3.

The first inductor conductor 40 electrically connects the first conductors 10A and 10B and the second conductors 11A and 11B. The first inductor conductor 40 connects end portions on one side of the first conductors 10A and 10B and end portions on one side of the second conductors 11A and 11B. The first inductor conductor 40 extends along the third direction D3. As viewed from the second direction D2, a width of the first inductor conductor 40 is greater than a width of each of the third inductor conductor 22 and the fourth inductor conductor 23.

The second inductor conductor 41 electrically connects the second conductors 11A and 11B to the third conductor 12 and the fourth conductor 13. The second inductor conductor 41 connects end portions on the other side of the second conductors 11A and 11B and end portions on the other side of the third conductor 12. The second inductor conductor 41 connects end portions on the other side of the second conductors 11A and 11B and end portions on the other side of the fourth conductor 13.

As described above, in the electronic component 1A according to the present embodiment, the second inductor conductor 41 connects the end portions on the other side of the second conductors 11A and 11B, the end portion on the other side of the third conductor 12, and the end portion on the other side of the fourth conductor 13. As described above, in the electronic component 1A, the second conductors 11A and 11B are connected to the third conductor 12 and the fourth conductor 13 by the second inductor conductor 41. As a result, in the electronic component 1A, an inductance can be secured in an inductor of the resonator 6A. Therefore, in the electronic component 1A, a Q-value can be improved.

In the electronic component 1A according to the present embodiment, the resonator 6A includes the first conductors 10A and 10B and the second conductors 11A and 11B. In this configuration, a current can be concentrated on the first inductor conductor 40. Therefore, in the electronic component 1A, as viewed from the second direction D2, the width of the first inductor conductor 40 is greater than the width of each of the third inductor conductor 22 and the fourth inductor conductor 23. As a result, in the electronic component 1A, it is possible to suppress the current from concentrating on the first inductor conductor 40.

Although the embodiments of the present disclosure have been described in the foregoing, the present disclosure is not necessarily limited to the above-described embodiments, and various modifications can be made without departing from the gist thereof.

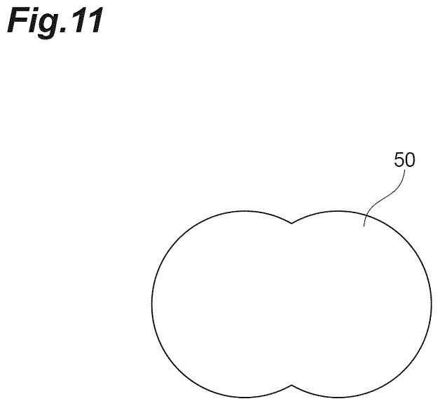

In the above embodiment, a mode in which the resonators 6 and 6A include the first conductors 10, 10A, and 10B has been described as an example. However, as illustrated in FIG. 11, the first conductor 50 has a shape in which a plurality of (two in the example illustrated in FIG. 11) circles overlap each other. Specifically, the first conductor 50 has a shape in which a part of each of a pair of adjacent circles overlaps. For example, two adjacent circles overlap each other such that an outer periphery of one circle passes through a center of the other circle. In this configuration, a sectional area of a section orthogonal to an extending direction of the first conductor 50 is greater than a sectional area of a section orthogonal to an extending direction of each of the third conductor 12, the fourth conductor 13, the fifth conductor 14, and the sixth conductor 15. As a result, it is possible to suppress the current from concentrating. The second conductor may have a configuration similar to the first conductor 50.

In the above embodiment, a mode in which the first conductors 10, 10A, and 10B and the second conductors 11, 11A, and 11B are connected by the first inductor conductors 20 and 40 has been described as an example. However, the first conductors 10, 10A, and 10B and the second conductors 11, 11A, and 11B may be further connected by another inductor conductor (connection conductor).

In the above embodiment, a mode in which the second inductor conductors 21 and 41 are one member has been described as an example. However, the second inductor conductor may include two members.

What is claimed is:

1. An electronic component comprising:
an element body formed by stacking a plurality of insulator layers; and
an inductor disposed in the element body,
wherein the inductor includes:
a first conductor, a second conductor, a third conductor, a fourth conductor, a fifth conductor, and a sixth conductor extending in a stacking direction of the plurality of insulator layers, and
a first connection conductor, a second connection conductor, a third connection conductor, and a fourth connection conductor,
the first connection conductor connects an end portion on one side of the first conductor in an extending direction of the first conductor and an end portion on one side of the second conductor in an extending direction of the second conductor,
the second connection conductor connects an end portion on the other side of the second conductor in the extending direction, an end portion on the other side of the third conductor in an extending direction of the third conductor, and an end portion on the other side of the fourth conductor in an extending direction of the fourth conductor,
the third connection conductor connects an end portion on one side of the third conductor in the extending direction and an end portion on one side of the fifth conductor in an extending direction of the fifth conductor, and
the fourth connection conductor connects an end portion on one side in the extending direction of the fourth conductor and an end portion on one side of the sixth conductor in an extending direction of the sixth conductor.

2. The electronic component according to claim 1, wherein the second connection conductor includes two members.

3. The electronic component according to claim 1, wherein the first conductor is disposed between the third conductor and the fourth conductor in a direction orthogonal to a facing direction in which the first conductor and the second conductor face each other as viewed from the stacking direction.

4. The electronic component according to claim 1, wherein the second conductor is disposed between the fifth conductor and the sixth conductor in a direction orthogonal to a facing direction in which the first conductor and the second conductor face each other as viewed from the stacking direction.

5. The electronic component according to claim 1, wherein the second connection conductor has a structure that is line-symmetric with respect to a straight line connecting the first conductor and the second conductor as viewed from the stacking direction.

6. The electronic component according to claim 1, wherein the first conductor includes a plurality of via conductors.

7. The electronic component according to claim 1, wherein the second conductor includes a plurality of via conductors.

8. The electronic component according to claim 1, wherein a sectional area of a section orthogonal to the extending direction of at least one of the first conductor and the second conductor is greater than a sectional area of a section orthogonal to the extending direction of each of the third conductor, the fourth conductor, the fifth conductor, and the sixth conductor.

9. The electronic component according to claim 1, wherein a width of the first connection conductor is greater than a width of each of the third connection conductor and the fourth connection conductor as viewed from the stacking direction.
